(19) United States
(12) Patent Application Publication
(10) Pub. No.: US 2006/0208347 A1
(43) Pub. Date: Sep. 21, 2006

(54) Semiconductor device package

(76) Inventor: Kidon Kim, Kaohsiung (TW)

Correspondence Address: Michael D. Bednarek;SHAWPITTMAN LLP, 1650 Tysons Boulevard, McLean, VA, 22102, US

(21) Appl. No.: 11/081,685

(22) Filed: Mar. 17, 2005

(51) Int. Cl. H01L 23/552

(52) U.S. Cl. 257/678

(57) ABSTRACT

A semiconductor device package includes a semiconductor device mounted and electrically coupled to the upper surface of a substrate, a package body encapsulating the semiconductor device against a portion of the upper surface of the substrate; and a metal ring formed on the upper surface of the substrate and connected to ground potential. The metal ring loops around the semiconductor device for providing electromagnetic interference shielding.

### BACKGROUND OF THE INVENTION

1. Field of the Invention

This invention relates to semiconductor device packages, and more specifically to semiconductor device packages which are shielded to protect against electromagnetic interference (EMI).

2. Description of the Related Art

Semiconductor device packages typically have electrical circuitry implemented on a circuit substrate, such as a printed circuit board or a ceramic substrate. The performance of the circuitry may be adversely affected by electromagnetic interference (EMI). Electromagnetic interference (EMI) is the generation of undesired electrical signals, or noise, in electronic system circuitry due to the unintentional coupling of impinging electromagnetic field energy.

The coupling of signal energy from an active signal net onto another signal net is referred to as crosstalk. Crosstalk is within-system EMI, as opposed to EMI from a distant source. Crosstalk is proportional to the length of the net parallelism and the characteristic impedance level, and inversely proportional to the spacing between signal nets.

Electronic systems are becoming smaller, and the density of electrical components in these systems is increasing. As a result, the dimensions of the average circuit element is decreasing, favoring the radiation of higher and higher frequency signals. At the same time, the operating frequency of these electrical systems is increasing, further favoring the incidence of high frequency EMI. EMI can come from electrical systems distant from a sensitive receiving circuit, or the source of the noise can come from a circuit within the same system (crosstalk or near source radiated emission coupling). The additive effect of all these sources of noise is to degrade the performance, or to induce errors in sensitive systems.

### SUMMARY OF THE INVENTION

It is therefore an object of the present invention to provide semiconductor device packages which are shielded to protect against electromagnetic interference (EMI).

To achieve the above listed and other objects, a semiconductor device package having features of the present invention generally includes a semiconductor device mounted and electrically coupled to the upper surface of a substrate, a package body encapsulating the semiconductor device against a portion of the upper surface of the substrate; and a metal ring formed on the upper surface of the substrate and connected to ground potential. The metal ring loops around the semiconductor device for providing electromagnetic interference shielding.

Alternatively, the metal ring may be replaced by a plurality of metal traces arranged around the semiconductor device for providing electromagnetic interference shielding. Preferably, some of the metal traces may be formed in a rectangular shape and respectively located at the corners of the substrate. In addition, all of the metal traces may be arranged along the edges of the substrate.

Preferably, the lower surface of the substrate may be provided with a ground plane for supplying ground potential and the metal ring (or each metal trace mentioned above) is electrically connected to the ground plane.

The present invention further provides another semiconductor device package including a semiconductor device electrically connected to a plurality of leads arranged about the periphery of the semiconductor device, a metal ring surrounding the semiconductor device for providing electromagnetic interference shielding, the metal ring being electrically isolated from the leads; and a package body formed over the semiconductor device, the leads and the metal ring. Each of the leads has one surface exposed from the lower surface of the package for making external electrical connection.

The metal ring is electrically isolated from the leads. This package may be provided with a die pad for receiving the semiconductor device and supplying ground potential and a plurality of tie bars for connecting the metal ring to the die pad. The leads may be arranged in a staggered multi-row pattern.

### BRIEF DESCRIPTION OF THE DRAWINGS

These and other features, aspects, and advantages of the present invention will be more fully understood by reading the following detailed description of the preferred embodiment, with reference made to the accompanying drawings as follows:

FIG. 1 is a cross sectional view of a semiconductor device package according to one embodiment of the present invention;

FIG. 2 is a top plan view of the substrate of FIG. 1;

FIG. 3 is a top plan view of another substrate suitable for use in the present invention;

FIG. 4 is a top plan view of another substrate suitable for use in the present invention;

FIG. 5 is a cross sectional view of a semiconductor device package according to another embodiment of the present invention;

FIG. 6 is a bottom plan view of a semiconductor device package according to another embodiment of the present invention; and

FIG. 7 is a bottom plan view of a semiconductor device package according to another embodiment of the present invention.

### DETAILED DESCRIPTION OF THE PREFERRED EMBODIMENT

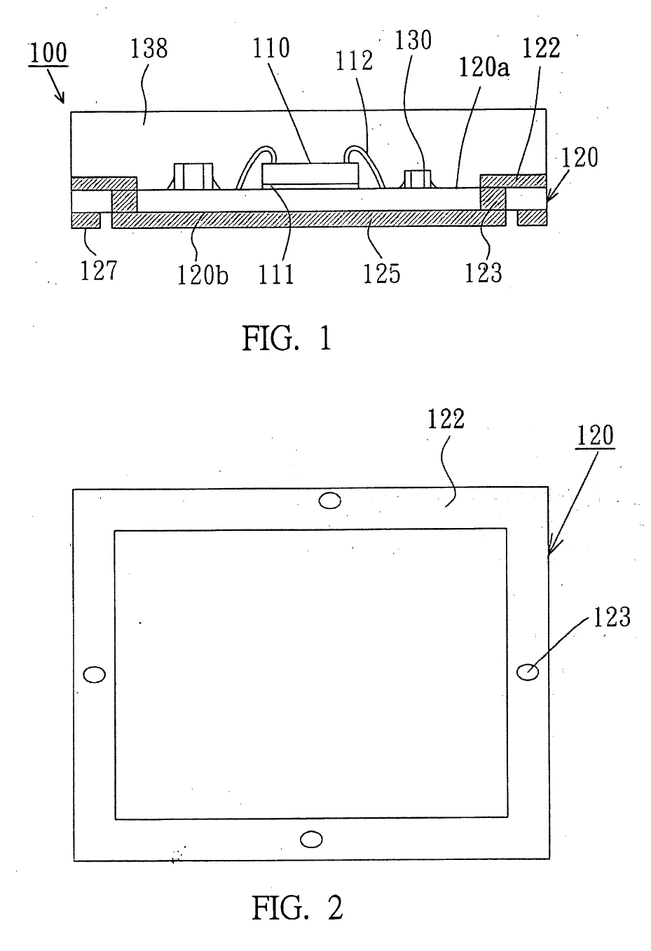

FIG. 1 illustrates a semiconductor device package 100 according to one embodiment of the present invention. The package 100 includes a semiconductor device 110 attached to the upper surface 120a of a substrate 120 by means of a conductive adhesive 111 such as a silver-filled epoxy or a non-conductive adhesive. A metal ring 122 is formed on the upper surface 120a of the substrate 120.

FIG. 2 is a top plan view of the substrate 120 of FIG. 1. As shown, the metal ring 122 loops around the semiconductor device 110 for providing electromagnetic interference shielding. The metal ring 122 is connected to a ground plane 125 by one or more dedicated vertical terminals (e.g., via 123) which may be provided at any location between the metal ring 122 and the ground plane 125, as desired. The ground plane 125 is formed on the lower surface 120b of the substrate 120 which is adapted for electrically joined to an electrical ground of an external printed circuit (PC) main board (not shown). It could be understood that the ground plane 125 is not an essential aspect of the present invention. If the ground plane 125 is skipped, the metal ring 122 may be directly joined to the electrical ground of the external PC board by the via 123.

As shown in FIG. 1, the semiconductor device 110 is connected to the substrate 120 by a plurality of bonding wires 112 and sealed in a package body 138 by a conventional transfer-molding process. The bonding wires 112 act as electrical input/output (I/O) connections to a first set of contacts (not shown), e.g., conductive traces or pads, provided on the upper surface 120a of the substrate 120. Alternatively, the semiconductor device 110 may be connected to the substrate 120 by a plurality of solder balls. The solder balls may be formed on an active surface of the semiconductor device 110 using one of any known bumping procedures. The upper surface 120a of the substrate 120 is also provided with a second set of contacts (not shown) for electrical coupling to SMT devices 130. For making electrical connection to an outside printed circuit board, the lower surface 120b of the substrate 120 is provided with a third set of contacts 127 which are electrically interconnected to the first set of contacts and the second set of contacts, and, usually, a plurality of solder balls (not shown) are mounted on the third set of contacts 127.

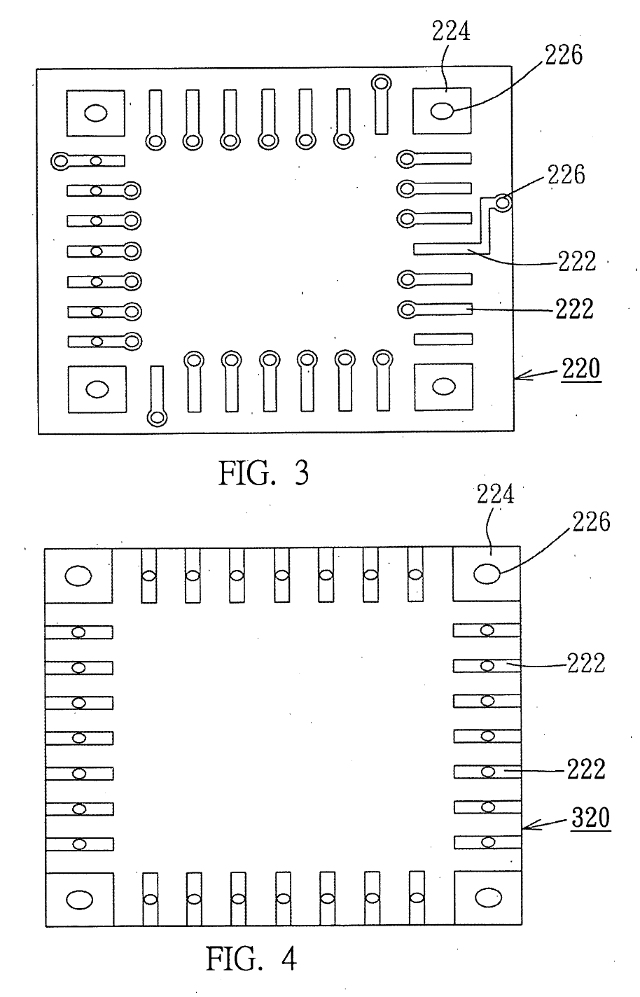

FIG. 3 is a top plan view of a substrate 220 suitable for use in the present invention. The substrate 220 is substantially identical to the substrate 120 of FIG. 2 with the exception that the substrate 220 is provided with a plurality of metal traces 222 and 224 instead of the metal ring 122. The metal traces 222 and 224 are arranged around the semiconductor device 120 (not shown in FIG. 3) for providing electromagnetic interference shielding. The metal traces 226 are formed in a rectangular shape and respectively located at the comers of the substrate 220. Each of the metal traces 222 and 224 is connected to ground potential. Specifically, each of the metal traces 222 and 224 is connected to one independent grounding portion (not shown) provided in the substrate 220 by a dedicated vertical terminal such as via 226. The grounding portion may be distributed in the substrate 220 in any available location, and are electrically joined to an electrical ground of an external printed circuit (PC) main board (not shown).

FIG. 4 is a top plan view of a substrate 320 suitable for use in the present invention. The substrate 320 is substantially identical to the substrate 220 of FIG. 3 with the exception that all of the metal traces 222 and 224 are arranged along the edges of the substrate 320.

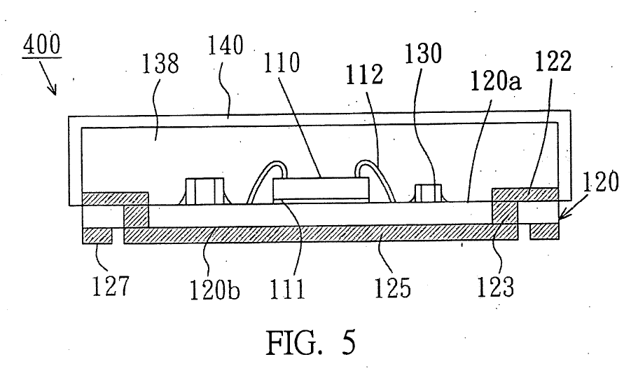

FIG. 5 illustrates a semiconductor device package 400 according to another embodiment of the present invention. The semiconductor device package 400 is substantially identical to the semiconductor package 100 of FIG. 1 with the exception that the semiconductor device package 400 further comprises a metal film 140 formed over the package body 138 and connected to the metal ring 122 for providing better EMI shielding. The metal film 140 may be replaced by a conductive paint layer or a conductive polymer layer. In addition, the surface of the metal film 140 may have a solder layer or a black-oxidation layer (not shown) formed thereon for mark ability.

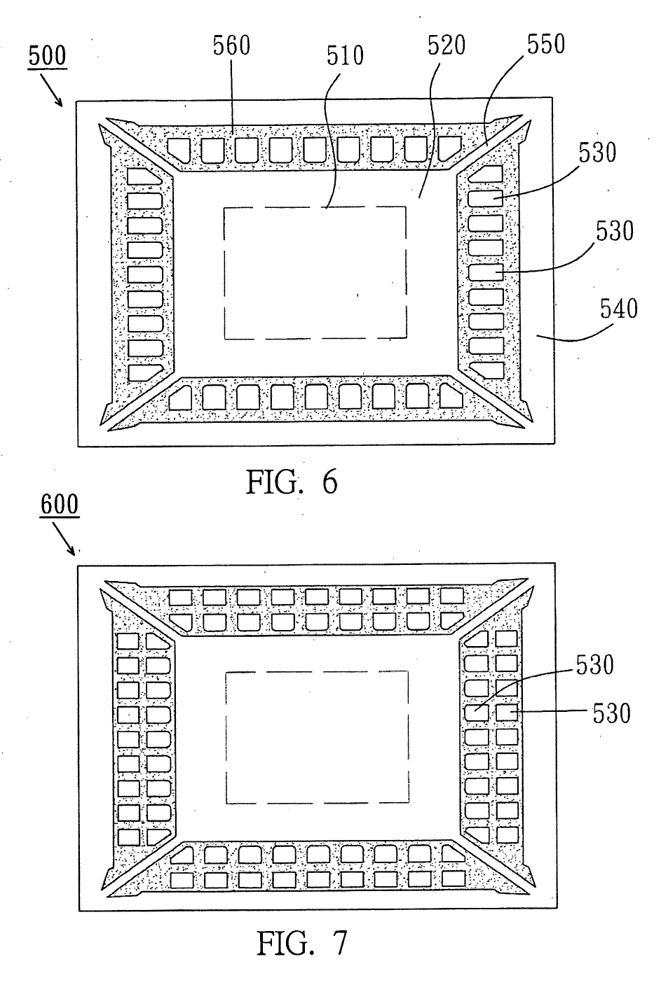

FIG. 6 illustrates a semiconductor device package 500 according to another embodiment of the present invention. The package 500 mainly includes a semiconductor device 510 attached to a die pad 520 and a plurality of leads 530 arranged about the periphery of the semiconductor device 510. The package 500 is provided with a rectangular metal ring 540 surrounding the semiconductor device 510 for providing electromagnetic interference shielding. As shown, the metal ring 540 is arranged at the periphery of the package 500 and connected to the die pad 510 via a plurality of tie bars 550. The metal ring 540 is separated from the leads by the insulating package body 560 such that it is electrically isolated from the leads 530. The semiconductor device 510 may be connected to the leads 530 by a plurality of bonding wires (not shown) and sealed in a package body 560 by a conventional transfer-molding process. The lower surface of each lead 530 is exposed from the lower surface of the package 500 for making external electrical connection. Preferably, the metal ring 540 is electrically joined to an electrical ground of an external printed circuit (PC) main board (not shown).

FIG. 7 illustrates a semiconductor device package 600 according to another embodiment of the present invention. The semiconductor device package 600 is substantially identical to the semiconductor package 500 of FIG. 6 with the exception that the leads 530 are arranged in a staggered two-row pattern.

It could be understood that the die pad 520 is not an essential aspect of the present invention and can be skipped such that the bottom surface of the semiconductor device 510 can be exposed from the lower surface of the package 500.

Although the invention has been explained in relation to its preferred embodiments, it is to be understood that many other possible modifications and variations can be made without departing from the spirit and scope of the invention as hereinafter claimed.

What is claimed is:

1. A semiconductor device package comprising:
a substrate having opposing upper and lower surfaces, the substrate being provided with a metal ring formed on the upper surface of the substrate and connected to ground potential;
a semiconductor device mounted and electrically coupled to the upper surface of the substrate; and
a package body encapsulating the semiconductor device against a portion of the upper surface of the substrate,
wherein the metal ring loops around the semiconductor device for providing electromagnetic interference shielding.

2. The semiconductor device package as claimed in claim 1, wherein the lower surface of the substrate is provided with a ground plane for supplying ground potential and a set of contacts for making external electrical connection wherein the metal ring is electrically connected to the ground plane.

3. The semiconductor device package as claimed in claim 2, further comprising at least one via formed in the substrate for electrically connecting the metal ring and the ground plane.

4. The semiconductor device package as claimed in claim 1, further comprising a conductive paint layer formed over the package body and connected to the metal ring.

5. The semiconductor device package as claimed in claim 1, further comprising a metal film formed over the package body and connected to the metal ring.

6. The semiconductor device package as claimed in claim 1, further comprising a conductive polymer layer formed over the package body and connected to the metal ring.

7. A semiconductor device package comprising:
a substrate having opposing upper and lower surfaces, the substrate being provided with a plurality of metal traces each formed on the upper surface of the substrate and connected to ground potential;
a semiconductor device mounted and electrically coupled to the upper surface of the substrate; and
a package body encapsulating the semiconductor device against a portion of the upper surface of the substrate,
wherein the metal traces are arranged around the semiconductor device for providing electromagnetic interference shielding.

8. The semiconductor device package as claimed in claim 7, wherein the lower surface of the substrate is provided with a ground plane for supplying ground potential and a set of contacts for making external electrical connection wherein each of the metal traces is electrically connected to the ground plane.

9. The semiconductor device package as claimed in claim 8, further comprising a plurality of vias formed in the substrate for electrically connecting the metal traces and the ground plane.

10. The semiconductor device package as claimed in claim 7, further comprising a conductive paint layer formed over the package body and connected to one of the metal traces.

11. The semiconductor device package as claimed in claim 7, further comprising a metal film formed over the package body and connected to one of the metal traces.

12. The semiconductor device package as claimed in claim 7, further comprising a conductive polymer layer formed over the package body and connected to one of the metal traces.

13. The semiconductor device package as claimed in claim 7, wherein some of the metal traces are formed in a rectangular shape and respectively located at the corners of the substrate.

14. The semiconductor device package as claimed in claim 7, wherein all of the metal traces are arranged along the edges of the substrate.

15. A semiconductor device package comprising:
a semiconductor device having a plurality of bonding pads formed thereon;
a plurality of leads arranged about the periphery of the semiconductor device, the leads being electrically connected to the bonding pads of the semiconductor device, respectively;
a metal ring surrounding the semiconductor device for providing electromagnetic interference shielding, the metal ring being electrically isolated from the leads; and
a package body formed over the semiconductor device, the leads and the metal ring,
wherein each of the leads has one surface exposed from the lower surface of the package for making external electrical connection.

16. The semiconductor device package as claimed in claim 15, further comprising a die pad for receiving the semiconductor device and a plurality of tie bars for connecting the metal ring to the die pad.

17. The semiconductor device package as claimed in claim 15, wherein the metal ring is arranged at the periphery of the package.

18. The semiconductor device package as claimed in claim 15, wherein the leads are arranged in a multi-row pattern.
